(19) United States
(12) Patent Application Publication
(10) Pub. No.: US 2025/0127026 A1
(43) Pub. Date: Apr. 17, 2025

(54) LASER SCRIBING METHOD AND DEVICE FOR PEROVSKITE THIN-FILM SOLAR CELL

(71) Applicant: Shenzhen Qinghong Laser Technology Co., Ltd, Shenzhen (CN)

(72) Inventors: Yanjun ZHAO, Shenzhen (CN); Kun GAO, Shenzhen (CN); Cheng LI, Shenzhen (CN)

(21) Appl. No.: 19/002,659

(22) Filed: Dec. 26, 2024

(30) Foreign Application Priority Data
Apr. 30, 2024 (CN) 202410533723.1

(51) Int. Cl. H10K 71/40; H10K 30/50

(52) U.S. Cl. CPC H10K 71/421; H10K 30/50

(57) ABSTRACT

A laser scribing method for perovskite thin-film solar cells is provided, in which a linearly polarized Gaussian beam is emitted by a laser, and converted into a circularly polarized beam through a quarter-wave plate. The circularly polarized beam is expanded to a target diameter by a beam expander system to obtain a target expanded beam. The target expanded beam is adjusted by an optical path adjustment system to enter a diffractive optical element (DOE) shaping module for beam shaping to obtain a shaped beam. The shaped beam is focused by an optical focusing module to obtain a focused beam with the focus on a surface film of a to-be-processed product, and the to-be-processed product is moved such that a groove is scribed thereon. A laser scribing device is also provided.

### CROSS-REFERENCE TO RELATED APPLICATIONS

This application claims the benefit of priority from Chinese Patent Application No. 202410533723.1, filed on Apr. 30, 2024. The content of the aforementioned application, including any intervening amendments made thereto, is incorporated herein by reference in its entirety.

### TECHNICAL FIELD

This application relates to photovoltaic thin-film cells and laser processing, and more particularly to a laser scribing method and device for a perovskite thin-film solar cell.

### BACKGROUND

As an emerging product in the photovoltaic field, perovskite thin-film solar cells are characterized by simple structure, adjustable light transmittance, high stability under low light intensity, and small temperature coefficient, making them highly promising for the long-term application and development. Moreover, the perovskite thin-film solar cells exhibit excellent applicability in the fields of construction, photovoltaic base stations, and customized products. The perovskite thin-film cells have attracted extensive attention over the past two years, and have been gradually put into the industrial production.

The perovskite thin-film solar cell offers several advantages: simple and short preparation process, high production efficiency, low material costs, no need for high-temperature conditions, high stability under poor light conditions, high light transmittance, adjustable shape, light weight and excellent flexibility, and thus have a broader application range.

The preparation process of single-junction perovskite thin-film solar cells includes three laser scribing steps, respectively P1, P2, and P3. It is required to perform the laser scribing after each coating operation. In the traditional laser scribing method, a nanosecond or picosecond laser beam is expanded, focused through an optical focusing module to obtain a focused laser spot for direct scribing. The resultant spot has a Gaussian energy distribution, which will easily lead to the occurrence of crater-like protrusions along the scribed lines and result in a larger heat-affected zone. The raised crater-like structure will severely impact the coating adhesion in the next laser scribing step, which in turn affects the performance of the perovskite thin-film solar cell. Additionally, the larger heat-affected zone will result in an increase in the dead area width after the P1, P2, and P3 laser scribing steps, reducing the effective power conversion area of the perovskite thin-film solar cell and weakening its power generation efficiency.

### SUMMARY

In view of the deficiencies in the existing preparation of perovskite thin-film solar cells that the traditional laser scribing methods tend to cause crater-like protrusions along the scribed lines and result in a larger heat-affected zone, this application provides a laser scribing method for film side of a perovskite thin-film solar cell.

In order to achieve the above object, in a first aspect, the present disclosure provides a laser scribing method for a perovskite thin-film solar cell comprising:
emitting, by a laser, a linearly polarized Gaussian beam to a quarter-wave plate along a preset direction; and converting, by the quarter-wave plate, the linearly polarized Gaussian beam into a circularly polarized beam;
adjusting a beam expander system to expand a diameter of the circularly polarized beam to a target value to output a target expanded beam;
adjusting, by an optical path adjustment system, the target expanded beam to travel to a diffractive optical element (DOE) shaping module for beam shaping to obtain a shaped beam;
focusing, by an optical focusing module, the shaped beam to obtain a focused beam with a focus on a surface film of a to-be-processed product; and
moving the to-be-processed product to scribe and groove the surface film of the to-be-processed product, wherein the surface film of the to-be-processed product comprises a glass substrate, a first electrode layer, a perovskite light-absorbing layer, and a second electrode layer, the first electrode layer is made from a transparent material, and the second electrode layer is made from a metal or a metal oxide.

In some embodiments, the surface film of the to-be-processed product is scribed and grooved through steps of:
in a first laser scribing step, coating the first electrode layer on the glass substrate to form a first laminate, and moving the first laminate to allow the focused beam to scribe and groove a to-be-etched area on the first electrode layer without damaging the glass substrate;
in a second laser scribing step, coating the perovskite light-absorbing layer on the first electrode layer to form a second laminate, and moving the second laminate to allow the focused beam to scribe and groove a to-be-etched area on the perovskite light-absorbing layer without damaging the first electrode layer; and
in a laser third scribing step, coating the second electrode layer on the perovskite light-absorbing layer to form the surface film, and moving the surface film to allow the focused beam to scribe and groove a to-be-etched area on the second electrode layer without damaging the perovskite light-absorbing layer;
wherein through the first laser scribing step, the second laser scribing step and the third laser scribing step, a scribed groove is formed to divide the surface film of the to-be-processed product into a plurality of sub-cells connected in series.

In some embodiments, the beam expander system comprises a plurality of zoom beam expanders varying in magnification; and the plurality of zoom beam expanders are configured to be adjusted in a manual or motorized manner to continuously expand the diameter of the circularly polarized beam to the target value, so as to output the target expanded beam.

In some embodiments, the optical path adjustment system comprises a first reflector and a second reflector; and
the step of adjusting the target expanded beam to travel to the DOE shaping module for beam shaping to obtain the shaped beam comprises:
adjusting the first reflector such that an angle between the first reflector and a direction of the target expanded beam is 45°;
adjusting the second reflector to be parallel to the first reflector, wherein the second reflector is spaced from the first reflector at a present distance; and
reflecting the target expanded beam sequentially by the first reflector and the second reflector to perpendicularly and centeredly enter the DOE shaping module for beam shaping to obtain the shaped beam.

In some embodiments, the optical path adjustment system further comprises a third reflector; the DOE shaping module is provided between the second reflector and the third reflector; and
before focusing the shaped beam to obtain the focused beam, the laser scribing method further comprises:
adjusting the third reflector to be parallel to the second reflector; and
reflecting, by the third reflector, the shaped beam output by the DOE shaping module to perpendicularly and centeredly enter the optical focusing module to obtain the focused beam with the focus on the surface film of the to-be-processed product.

In some embodiments, the shaped beam comprises a flat-top beam, or an array of a plurality of split beams in a linear arrangement with an arrangement direction being perpendicular to the scribed groove of a to-be-etched area on the surface film of the to-be-processed product; and
the flat-top beam is a square flat-top beam, a circular flat-top beam or an elliptical flat-top beam.

In some embodiments, in the first laser scribing step, the linearly polarized Gaussian beam emitted by the laser has a wavelength of 532-1064 nm and a pulse width ranging from 200 fs to 100 ns, and a width of a first part of the scribed groove is 20-80 μm;

in the second laser scribing step, the linearly polarized Gaussian beam emitted by the laser has a wavelength of 355-1064 nm, and a pulse width ranging from 200 fs to 100 ns, and a width of a second part of the scribed groove is 30-200 μm; and
in the third laser scribing step, the linearly polarized Gaussian beam emitted by the laser has a wavelength of 266-532 nm, and a pulse width ranging from 200 fs to 100 ns, and a width of a third part of the scribed groove is 30-100 μm.

In some embodiments, in the first laser scribing step, the linearly polarized Gaussian beam emitted by the laser has a wavelength of 1064 nm and a pulse width of 10 ps, and the width of the first part of the scribed groove is 30 μm;
in the second laser scribing step, the linearly polarized Gaussian beam emitted by the laser has a wavelength of 532 nm and a pulse width of 10 ps, and the width of the second part of the scribed groove is 50 μm; and
in the third laser scribing step, the linearly polarized Gaussian beam emitted by the laser has a wavelength of 355 nm and a pulse width of 10 ps, and the width of the third part of the scribed groove is 30 μm.

In some embodiments, a power of the laser is 20-90 W, a frequency of the laser is adjustable within a range from 100 kHz to 6 MHz, and a processing speed of the laser is 500 mm/s to 30,000 mm/s.

Based on the same technical idea, in a second aspect, the present disclosure also provides a laser scribing device for implementing the above laser scribing method.

Compared to the prior art, the present disclosure has the following beneficial effects.

This application provides a laser scribing method and device for scribing and grooving a surface film of a perovskite thin-film solar cell. In the scribing method provided herein, a linearly polarized Gaussian beam is emitted by a laser along a preset direction to a quarter-wave plate, and converted into a circularly polarized beam; the circularly polarized beam is expanded by a beam expander system to a target diameter to obtain a target expanded beam; the target expanded beam is adjusted by an optical path adjustment system to enter a DOE shaping module for beam shaping to generate a shaped beam; and the shaped beam is focused on a surface film of a to-be-processed product, and the to-be-processed product is moved to scribe a groove thereon. Based on these steps, the present disclosure effectively avoids the occurrence of crater-like protrusions along the groove edges, thereby enhancing the photoelectric performance of the perovskite thin-film cells and reducing the risk of damaging the film layer during the subsequent assembly to keep the power conversion efficiency stable.

Regarding the method of the present disclosure, in the first laser scribing step (P1), an edge thermal effect is less than 2 μm and an edge protrusion is less than 10 nm; in the second laser scribing step (P2), the edge thermal effect is less than 2 μm, and the edge protrusion is less than 10 nm; and in the third laser scribing step (P3), the edge thermal effect is less than 5 μm, and the edge protrusion is less than 100 nm.

### BRIEF DESCRIPTION OF THE DRAWINGS

In order to illustrate the technical solutions in the present disclosure more clearly, the accompanying drawings needed in the description of the embodiments will be briefly described below. It is evident that presented in the accompanying drawings described below are only some embodiments of the present disclosure. For those of ordinary skill in the art, other accompanying drawings can be obtained based on these accompanying drawings without making creative effort.

FIG. 1 is a flowchart of a laser scribing method for a perovskite thin-film solar cell in accordance with an embodiment of the present disclosure;

FIG. 2 is an optical structure design diagram based on FIG. 1;

FIGS. 3A-3C schematically illustrate scribing steps of the laser scribing process in accordance with an embodiment of the present disclosure;

FIG. 4A is an image showing a smooth cut produced by a linearly polarized beam in a single direction;

FIG. 4B is an image showing a uniform effect produced by a circularly polarized beam in all directions;

FIG. 5A schematically shows splitting of a beam into multiple light spots by a diffractive optical element (DOE) shaping module in accordance with an embodiment of the present disclosure;

FIG. 5B is an energy distribution diagram of the multiple light spots in accordance with an embodiment of the present disclosure;

FIG. 5C schematically shows a cross-sectional energy distribution of the multiple light spots in accordance with an embodiment of the present disclosure;

FIG. 5D is an energy distribution diagram of a flat-top beam shaped by the DOE shaping module in accordance with an embodiment of the present disclosure;

FIG. 5E is a cross-sectional energy distribution of the flat-top beam shaped by the DOE shaping module in accordance with an embodiment of the present disclosure; and

FIGS. 6A-6B schematically show scribed grooves on the perovskite thin-film solar cell generated based on the method in FIG. 1.

In the figures: 10—laser; 20—quarter-wave plate; 30—beam expander system; 40—diffractive optical element (DOE) shaping module; 31—first reflector; 32—second reflector; 33—third reflector; 50—optical focusing module; P1—first laser scribing step; P2—second laser scribing step; and P3—third laser scribing step.

### DETAILED DESCRIPTION OF EMBODIMENTS

In order to make the advantages and features of the present disclosure more understandable for those of ordinary skill in the art, the present disclosure will be described in detail below in conjunction with the embodiments and accompanying drawings. It is evident that described below are only some embodiments of the present disclosure and not all embodiments. Based on the embodiments provided herein, any other embodiments obtained by those of ordinary skill in the art without making creative effort shall fall within the scope of the present disclosure.

As used herein, terms “include”, “comprise” and their variations are intended to cover non-exclusive inclusions. As used herein, the terms such as “first” and “second” are for distinguishing different objects and are not intended to describe a specific sequence. As used herein, the positional terms such as “up”, “down”, “left”, “right”, “front”, “back” and “side” are intended to illustrate the relative positions shown in the drawings, instead of meaning that the device or element must be arranged in such configuration or orientation.

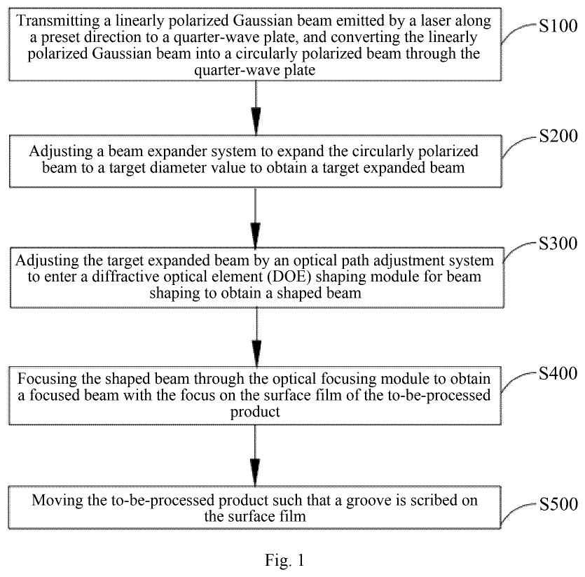

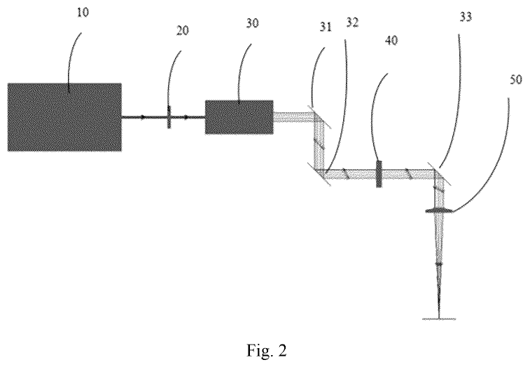

As shown in FIGS. 1-2, an embodiment of the present disclosure provides a laser scribing method used in the manufacturing process of a perovskite thin-film solar cell, which is performed as follows.

Step (S100) A linearly polarized Gaussian beam is emitted by a laser 10 along a preset direction to reach a quarter-wave plate 20 to be converted into a circularly polarized beam.

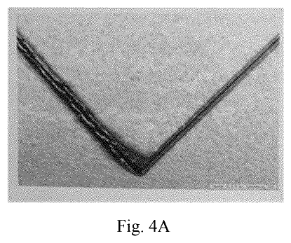

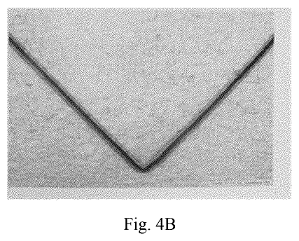

In an embodiment, the laser 10 is configured to generate the desired linearly polarized Gaussian laser beam, which is transmitted in the preset direction to enter the quarter-wave plate 20. An angle of the quarter-wave plate 20 is adjusted to convert the linearly polarized beam into a circularly polarized beam. By using the quarter-wave plate 20, the original linearly polarized beam, which has differential processing effects in horizontal and vertical directions, is transformed into the circularly polarized beam which can offer the identical processing effect in both directions, as shown in FIGS. 4A-B.

In some embodiments, the laser 10 is configured to generate the desired linearly polarized Gaussian laser beam, which is transmitted in the preset direction to enter the quarter-wave plate 20, and then the linearly polarized beam is converted by the quarter-wave plate 20 into a circularly polarized beam. A power of the laser 10 is 20-90 W, a frequency of the laser 10 is adjustable within a range from 100 KHz to 6 MHz, and a processing speed of the laser 10 is 500-30,000 mm/s.

The effectiveness of laser scribing and grooving has a significant impact on the photoelectric performance of the perovskite thin-film cells. The laser etching depth must be strictly controlled, with the goal of thoroughly clearing the film layer while avoiding crater-like protrusions and heat-affected zones, and ensuring good linear uniformity.

It should be noted that in the present disclosure, the laser 10 can be any laser product or optical module that can produce the same effect. The quarter-wave plate 20 can be an optical device or module consisting of one or more optical lenses that produce the same effect, without limitation.

Step (S200) The circularly polarized beam is expanded by a beam expander system 30 to a target diameter to obtain a target expanded beam.

In an embodiment, the beam expander system 30 is configured to expand and shape the circularly polarized beam to meet the target diameter requirement of the DOE shaping module 40. Specifically, the beam expander system 30 includes a plurality of zoom beam expanders varying in magnification, such as 1-4×, 1-8×, 2-8×, and 2-10×. and the plurality of zoom beam expanders are configured to be adjusted in a manual or motorized manner to continuously expand the diameter of the circularly polarized beam to the target value, so as to meet the target diameter requirement of the DOE shaping module 40.

In some embodiments, the beam expander system 30 can be a product in the art, such as a beam expander. The beam expander is configured to adjust continuously the magnifications of the circularly polarized beam after passing through the quarter-wave plate 20, so as to expand the beam to the target value, forming the required target expanded beam.

It should be noted that in the present disclosure, the beam expander system 30 can be any optical device or module that produces the same or similar beam expansion effect, or it can be a self-designed optical device or module composed of one or more optical lenses to achieve the same beam expansion effect, without limitation.

Step (S300) The target expanded beam is adjusted by an optical path adjustment system to enter a DOE shaping module 40 for beam shaping to generate a shaped beam.

In an embodiment, the optical path adjustment system is configured to adjust and guide the transmission of light, preventing energy loss during the light transmission process. In use, it is necessary to properly set up the optical path adjustment system. Specifically, the optical path adjustment system includes a first reflector 31 and a second reflector 32. The first reflector 31 is provided in front of the target expanded beam. And the second reflector 32 is provided at a certain distance from the first reflector 31 and aligned parallel to it. The target expanded beam is sequentially reflected by the first reflector 31 and the second reflector 32 to perpendicularly and centeredly enter the DOE shaping module 40 for beam shaping to obtain the shaped beam.

In some embodiments, the DOE shaping module 40 can be a DOE shaping lens. An angle between the first reflector 31 and a direction of the target expanded beam is 45°. Simultaneously, the second reflector 32 is adjusted to be parallel to and spaced from the first reflector 31 at a present distance such that the reflection light is perpendicular to the incident light, thereby preserving the light energy. The target expanded beam is sequentially reflected by the first reflector 31 and the second reflector 32 to perpendicularly and centeredly enter the DOE shaping lens for beam shaping to obtain the shaped beam. After entering the DOE shaping lens, the target expanded beam is either shaped into a flat-top beam or an array of a plurality of split beams. The flat-top beam is a square flat-top beam, a circular flat-top beam or an elliptical flat-top beam. The number of split beams in the array can be 1, 2, 3, etc., and the energy of individual split beam can be the same or different.

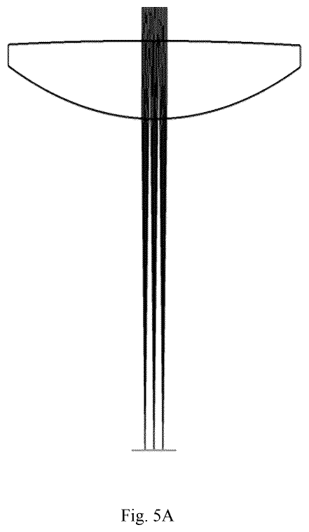

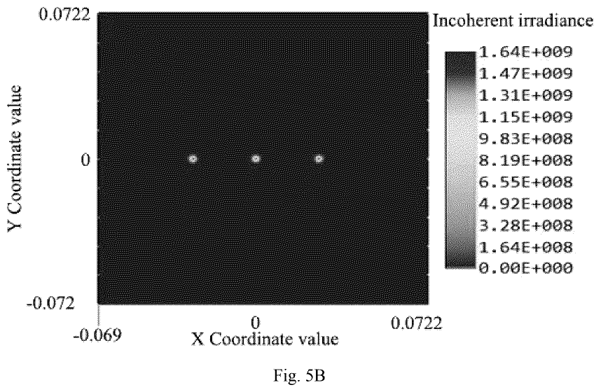

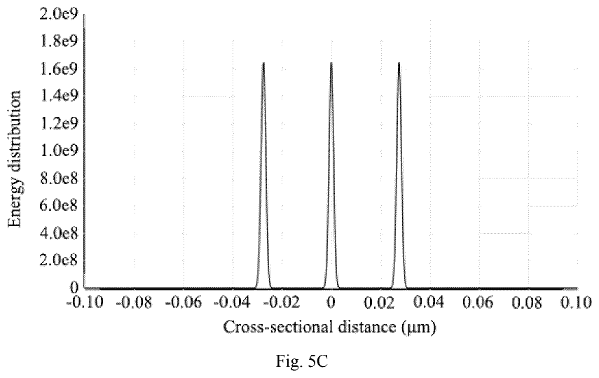

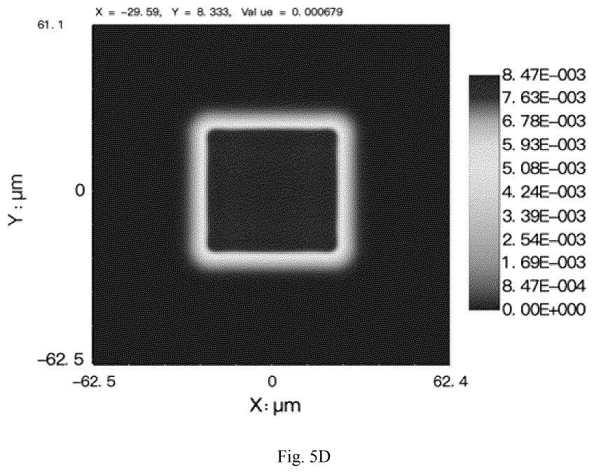

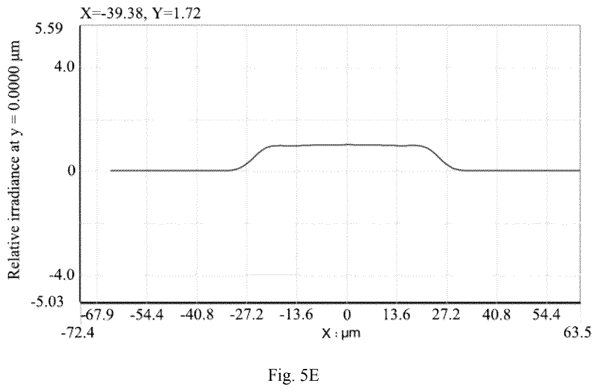

For example, FIG. 5D is an energy distribution diagram of the flat-top beam shaped by the DOE shaping module of the present disclosure. As shown in FIG. 5D, the X-axis represents the horizontal position in micrometers (μm), ranging from −62.5-62.4 μm, while the Y-axis represents the vertical position in μm, ranging from −62.5-61.1 μm. The right side shows the corresponding incoherent irradiance values, which from top to bottom are 8.47E-003, 7.63E-003, 6.78E-003, 5.93E-003, 5.08E-003, 4.24E-003, 3.39E-003, 2.54E-003, 1.69E-003, 8.47E-004, and 0.00E+000. When the X is-29.59 μm and the Y is 8.333 μm, the corresponding energy distribution value is 0.000679.

And FIG. 5E is a cross-sectional energy distribution of the flat-top beam shaped by the DOE shaping module of the present disclosure. As shown in FIG. 5E, the X-axis represents the horizontal position in μm, ranging from −72.4-63.5 μm, and the Y-axis represents the vertical position in μm, ranges from −5.03-5.59 μm with the relative irradiance at y=0.000 μm and units in μm. When the X is-39.38 μm and Y is 1.72 μm, the cross-sectional energy distribution is illustrated in FIG. 5E.

When the target expanded beam is shaped into a flat-top beam after entering the DOE shaping lens, it results in a homogeneous beam with a uniform energy distribution. This uniformity minimizes edge thermal effects and reduces the occurrence of crater-like protrusions during the fine processing of the grooves.

When the target expanded beam is split and shaped into an array of n beams (where n=1, 2, 3, . . . ) and dividing a single focal point into n beam spots for a more uniform energy distribution, this process leverages the advantages of Gaussian beam energy concentration and high processing efficiency. As shown in FIGS. 5A-5C, after passing through the DOE shaping lens, the beam is split into multiple light spots, forming an energy distribution pattern of the array of beams. Specifically, FIG. 5B is an energy distribution diagram of the multiple light spots by the DOE shaping module of the present disclosure, with an example of splitting into an array of three beams. As shown in FIG. 5B, the X-axis represents the horizontal position, ranging from −0.072 to 0.0722, while the Y-axis represents the vertical position, ranging from −0.069 to 0.0722. The right side shows the corresponding incoherent irradiance values, which from top to bottom are 1.64E+009, 1.47E+009, 1.31E+009, 1.15E+009, 9.83E+008, 8.19E+008, 6.55E+008, 4.92E+008, 3.28E+008, 1.64E+008, and 0.00E+000. FIG. 5C is a cross-sectional view of the energy distribution of the beam split into multiple light spots by the DOE shaping module of the present disclosure, with an example of splitting into three array beams. As shown in FIG. 5C, the X-axis represents the cross-sectional distance, ranging from −0.10-0.10 μm, with units in μm and a sectional spacing of 0.02 μm, corresponding to −0.10 μm, −0.08 μm, −0.06 μm, −0.04 μm, −0.02 μm, 0 μm, 0.02 μm, 0.04 μm, 0.06 μm, 0.08 μm, and 0.10 μm. The Y-axis represents the energy distribution, with values ranging from 0-2.0e9, with a distribution spacing of 2.0e, corresponding to 2.0e8, 4.0e8, 6.0e8, 8.0e8, 1.0e9, 1.2e9, 1.4e9, 1.6e9, 1.8e9, and 2.0e9.

In some embodiments, the target expanded beam is incident onto the first reflector 31 at 45°. The first reflector 31 is adjusted to reflect the first reflected beam at an angle that matches the incident angle, with the ideal angle between the target expanded beam and the first reflected beam being 90°. Then the first reflected beam is incident onto the second reflector 32 at 45°. The second reflector 32 is adjusted to reflect the second reflected beam at an angle that matches the incident angle, with the ideal angle between the first reflected beam and the second reflected beam being 90°. Afterward, the beam is shaped by the DOE shaping lens.

It should be noted that the optical path adjustment system herein can be any optical product device or module that produces the same or similar effects. It can also be a self-designed optical device or module composed of one or more optical lenses to achieve the same optical path adjustment effect, without limitation.

Step (S400) The shaped beam is focused on a surface film of a to-be-processed product.

In an embodiment, the optical focusing module 50 can be a focusing lens. Before the shaped beam passes through the optical focusing module 50, the optical path adjustment system further includes a third reflector 33. The DOE shaping module 40 is provided between the second reflector 32 and the third reflector 33, with the position of the third reflector 33 being adjusted to be parallel to the second reflector 32.

At this point, the shaped beam output by the DOE shaping module 40, is reflected by the third reflector 33 to perpendicularly and centeredly enter the optical focusing module 50 to obtain the focused beam.

In some embodiments, the shaped beam is incident onto the third reflector 33 at 45°. The third reflector 33 is adjusted to reflect the third reflected beam at an angle that matches the incident angle, where the ideal angle between the shaped beam and the third reflected beam is 90°. Then, the third reflected beam passes perpendicularly and centeredly through the optical focusing module 50 to obtain the focused beam with the focus on the surface film of the to-be-processed product.

It should be noted that the optical focusing module 50 herein can be any optical product device or module that produces the same or similar effect. It can also be a self-designed optical device or module composed of one or more optical lenses to achieve the same optical path adjustment effect, without limitation.

Step (S500) The to-be-processed product is moved to scribe and groove the surface film of the to-be-processed product.

In an embodiment, the relative movement is performed by moving the surface film of the to-be-processed product or the focusing lens, and during the movement process, the laser scribing and grooving are performed within a to-be-etched area on the surface film of the to-be-processed product. The surface film of the to-be-processed product includes a glass substrate, a first electrode layer, a perovskite light-absorbing layer, and a second electrode layer, where the first electrode layer is made from a transparent material, and the second electrode layer is made from a metal or a metal oxide.

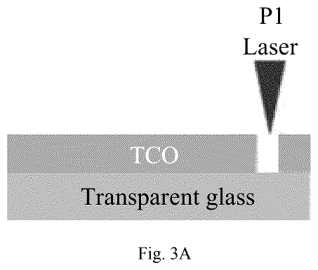

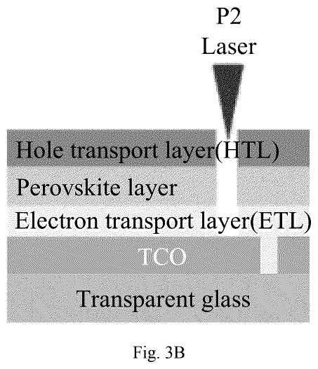

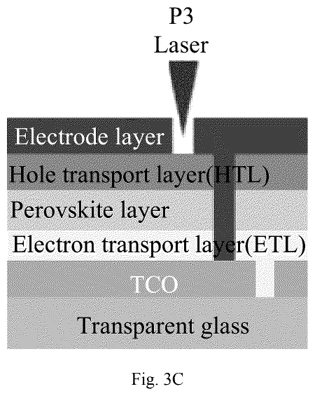

Referring to an embodiment shown in FIGS. 3A-3C, the preparation process of the perovskite thin-film solar cells includes three laser scribing steps. It is required to perform the laser scribing after each coating operation, with the etched lines needed to be parallel. The laser scribing method vaporizes the corresponding film layers on the to-be-etched areas on the surface film of the to-be-processed product, forming a scribed groove that divides the surface film of the to-be-processed product into a plurality of sub-cells, each approximately 3-12 mm in width and connected in series. Thus, individual modules that block current conduction are formed to achieve the effects of increasing voltage and connecting cells in series.

As shown in FIG. 3A, in a first laser scribing step (P1), the first electrode layer (TCO) is coated on the glass substrate to form a first laminate. A to-be-etched area on the first electrode layer (TCO) is scribed and grooved by the focused beam (laser) by moving the first laminate without damaging the glass substrate. The linearly polarized Gaussian beam emitted by the laser has a wavelength of 532-1064 nm and a pulse width ranging from 200 fs to 100 ns, and a width of a first part of the scribed groove is 20-80 μm

In some embodiments, the linearly polarized Gaussian beam emitted by the laser has a wavelength of 1064 nm and a pulse width of 10 ps, and the width of the first part of the scribed groove is 30 μm.

Regarding the method of the present disclosure, in the first laser scribing step (P1), an edge thermal effect is less than 2 μm and an edge protrusion is less than 10 nm.

As shown in FIG. 3B, in a second laser scribing step (P2), the perovskite light-absorbing layer is coated on the first electrode layer (TCO) to form a second laminate. The perovskite light-absorbing layer includes an electron transport layer (ETL), a perovskite layer, and a hole transport layer (HTL). A to-be-etched area on the perovskite light-absorbing layer is scribed and grooved by the focused beam (laser) by moving the second laminate without damaging the first electrode layer (TCO). The linearly polarized Gaussian beam emitted by the laser has a wavelength of 355-1064 nm, and a pulse width ranging from 200 fs to 100 ns, and a width of a second part of the scribed groove is 30-200 μm.

In some embodiments, the linearly polarized Gaussian beam emitted by the laser has a wavelength of 532 nm and a pulse width of 10 ps, and the width of the second part of the scribed groove is 50 μm.

Regarding the method of the present disclosure, in the second laser scribing step (P2), the edge thermal effect is less than 2 μm and the edge protrusion is less than 10 nm.

As shown in FIG. 3C, in a third laser scribing step (P3), the second electrode layer (Au) is coated on the perovskite light-absorbing layer to form the surface film. A to-be-etched area on the second electrode layer (Au) is scribed and grooved by the focused beam (laser) by moving the surface film without damaging the perovskite light-absorbing layer. The linearly polarized Gaussian beam emitted by the laser has a wavelength of 266-532 nm, and a pulse width ranging from 200 fs to 100 ns, and a width of a third part of the scribed groove is 30-100 μm.

In some embodiments, the linearly polarized Gaussian beam emitted by the laser has a wavelength of 355 nm and a pulse width of 10 ps, and the width of the third part of the scribed groove is 30 μm.

Regarding the method of the present disclosure, in the third laser scribing step (P3), the edge thermal effect is less than 5 μm and the edge protrusion is less than 100 nm.

In summary, as shown in FIG. 5A, for the first laser scribing step (P1), the second laser scribing step (P2) and the third laser scribing step (P3), the shaped beam that has passed through the DOE shaping module 40 is preferably a circular flat-top beam or split into 3, 4, or 5 array of beams. FIG. 5A schematically shows splitting of the beam into multiple light spots by the DOE shaping module 40, with an array of beam split into three light spots arranged in a line. And the arrangement direction of these light spots is perpendicular to the scribed groove on the to-be-etched area on the surface film of the to-be-processed product.

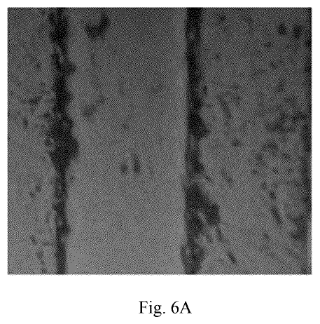

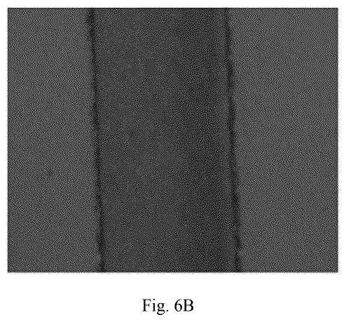

As shown in FIGS. 6A-6B, through the first laser scribing step (P1), the second laser scribing step (P2), and the third laser scribing step (P3), the scribed groove is formed. The “dead zone” of the scribed groove, which cannot contribute to photoelectric conversion in perovskite photovoltaic cells, is a significant factor affecting the photoelectric conversion efficiency of the cells. For example, in the first laser scribing step (P1), the width of the first part of the scribed groove is 30 μm, in the second laser scribing step (P2), the width of the second part of the scribed groove is 50 μm, and in the third laser scribing step (P3), the width of the third part of the scribed groove is 30 μm. The width of the “dead zone” can be reduced to less than 150 μm. Based on these steps, the present disclosure effectively avoids the occurrence of crater-like protrusions along the groove edges, thereby enhancing the photoelectric performance of the perovskite thin-film cells and reducing the risk of damaging the film layer during the subsequent assembly to keep the power conversion efficiency stable.

Based on the same technical concept, the disclosure also provides a device for scribing and grooving a surface film of a perovskite thin-film solar cell for implementing the above laser scribing method.

Compared to the prior art, the present disclosure has the following beneficial effects.

This application provides a laser scribing method and device for scribing and grooving a surface film of a perovskite thin-film solar cell. In the scribing method provided herein, a linearly polarized Gaussian beam is emitted by a laser along a preset direction to a quarter-wave plate, and converted into a circularly polarized beam; the circularly polarized beam is expanded by a beam expander system to a target diameter to obtain a target expanded beam; the target expanded beam is adjusted by an optical path adjustment system to enter a DOE shaping module for beam shaping to generate a shaped beam; and the shaped beam is focused on a surface film of a to-be-processed product, and the to-be-processed product is moved to scribe a groove thereon. Based on these steps, the present disclosure effectively avoids the occurrence of crater-like protrusions along the groove edges, thereby enhancing the photoelectric performance of the perovskite thin-film cells and reducing the risk of damaging the film layer during the subsequent assembly to keep the power conversion efficiency stable.

Regarding the method of the present disclosure, in the first laser scribing step (P1), an edge thermal effect is less than 2 μm and an edge protrusion is less than 10 nm; in the second laser scribing step (P2), the edge thermal effect is less than 2 μm, and the edge protrusion is less than 10 nm; and in the third laser scribing step (P3), the edge thermal effect is less than 5 μm, and the edge protrusion is less than 100 nm.

Those of ordinary skill in the art will appreciate that the embodiments of the present disclosure can be provided as methods, systems, or computer program products. Thus, this application may take the form of fully hardware embodiments, fully software embodiments, or a combination thereof. Furthermore, this application may be embodied as a computer program product on one or more computer-readable storage media (including but not limited to disk storage devices, compact disc read-only memory (CD-ROMs), optical storage, etc.) that contain computer-usable program code.

This application is described with reference to flowcharts and/or block diagrams of methods, devices (systems), and computer program products according to the embodiments of the present disclosure. It should be understood that each process and/or block in the flowcharts and/or block diagrams, as well as combinations of these processes and/or blocks, can be implemented by computer program instructions. These computer program instructions may be provided to a general-purpose computer, a dedicated computer, an embedded processor, or other programmable data processing devices to configure a machine. This machine, when operated by the computer or other programmable data processing devices, produces an apparatus that performs the functions specified in one or more processes of the flowchart and/or one or more blocks of the block diagram.

These computer program instructions may also be stored in a computer-readable storage medium that can be used to configure a computer or other programmable data processing device to operate in a specific manner. The instructions stored in the computer-readable storage medium produce an article of manufacture that includes the instructions, and implements the functions specified in one or more processes of the flowchart and/or one or more blocks of the block diagram.

The computer program instructions can also be loaded onto a computer or other programmable data processing devices, causing the computer or other programmable devices to execute a series of operational steps to produce a machine-implemented process. As a result, the instructions executed by the computer or other programmable devices provide steps for performing the functions specified in one or more processes of the flowchart and/or one or more blocks of the block diagram.

It should be noted that reference symbols placed in parentheses in the claims are not intended to limit the scope of the claims. As used herein, term “comprising” does not exclude the presence of components or steps not listed in the claims. As used herein, terms “one” or “a” before a component does not preclude the presence of multiple such components. This disclosure may be implemented using hardware that includes several different components or using appropriately programmed computers. In claims that enumerate several units of a device, some of these units may be embodied by the same hardware item. As used herein, terms “first”, “second”, “third” and the like are not meant to indicate any specific order and can be interpreted as names.

Though the present disclosure has been described in detail above with reference to preferred embodiments, those of ordinary skill in the art can still make various changes and modifications to the technical solutions of the present disclosure. It should be understood that those changes and modifications made without departing from the spirit of the present disclosure shall fall within the scope of the disclosure defined by the appended claims.

What is claimed is:

1. A laser scribing method for a perovskite thin-film solar cell, comprising:
emitting, by a laser, a linearly polarized Gaussian beam to a quarter-wave plate along a preset direction; and converting, by the quarter-wave plate, the linearly polarized Gaussian beam into a circularly polarized beam;
adjusting a beam expander system to expand a diameter of the circularly polarized beam to a target value to output a target expanded beam;
adjusting, by an optical path adjustment system, the target expanded beam to travel to a diffractive optical element (DOE) shaping module for beam shaping to obtain a shaped beam;
focusing, by an optical focusing module, the shaped beam to obtain a focused beam with a focus on a surface film of a to-be-processed product; and
moving the to-be-processed product relative to the optical focusing module to scribe and groove the surface film of the to-be-processed product, wherein the surface film of the to-be-processed product comprises a glass substrate, a first electrode layer, a perovskite light-absorbing layer, and a second electrode layer, the first electrode layer is made from a transparent material, and the second electrode layer is made from a metal or a metal oxide.

2. The laser scribing method of claim 1, wherein the surface film of the to-be-processed product is scribed and grooved through steps of:
in a first laser scribing step, coating the first electrode layer on the glass substrate to form a first laminate, and moving the first laminate to allow the focused beam to scribe and groove a to-be-etched area on the first electrode layer without damaging the glass substrate;
in a second laser scribing step, coating the perovskite light-absorbing layer on the first electrode layer to form a second laminate, and moving the second laminate to allow the focused beam to scribe and groove a to-be-etched area on the perovskite light-absorbing layer without damaging the first electrode layer; and
in a third laser scribing step, coating the second electrode layer on the perovskite light-absorbing layer to form the surface film, and moving the surface film to allow the focused beam to scribe and groove a to-be-etched area on the second electrode layer without damaging the perovskite light-absorbing layer;
wherein through the first laser scribing step, the second laser scribing step and the third laser scribing step, a scribed groove is formed to divide the surface film of the to-be-processed product into a plurality of sub-cells connected in series.

3. The laser scribing method of claim 1, wherein the beam expander system comprises a plurality of zoom beam expanders varying in magnification; and the plurality of zoom beam expanders are configured to be adjusted in a manual or motorized manner to continuously expand the diameter of the circularly polarized beam to the target value, so as to output the target expanded beam.

4. The laser scribing method of claim 1, wherein the optical path adjustment system comprises a first reflector and a second reflector; and
the step of adjusting the target expanded beam to travel to the DOE shaping module for beam shaping to obtain the shaped beam comprises:
adjusting the first reflector such that an angle between the first reflector and a direction of the target expanded beam is 45°;
adjusting the second reflector to be parallel to the first reflector, wherein the second reflector is spaced from the first reflector at a present distance; and
reflecting the target expanded beam sequentially by the first reflector and the second reflector to perpendicularly and centeredly enter the DOE shaping module for beam shaping to obtain the shaped beam.

5. The laser scribing method of claim 4, wherein the optical path adjustment system further comprises a third reflector; the DOE shaping module is provided between the second reflector and the third reflector; and
before focusing the shaped beam to obtain the focused beam, the laser scribing method further comprises:
adjusting the third reflector to be parallel to the second reflector; and
reflecting, by the third reflector, the shaped beam output by the DOE shaping module to perpendicularly and centeredly enter the optical focusing module to obtain the focused beam with the focus on the surface film of the to-be-processed product.

6. The laser scribing method of claim 2, wherein the shaped beam comprises a flat-top beam, or an array of a plurality of split beams in a linear arrangement with an arrangement direction being perpendicular to the scribed groove of a to-be-etched area on the surface film of the to-be-processed product; and
the flat-top beam is a square flat-top beam, a circular flat-top beam or an elliptical flat-top beam.

7. The laser scribing method of claim 6, wherein in the first laser scribing step, the linearly polarized Gaussian beam emitted by the laser has a wavelength of 532-1064 nm and a pulse width ranging from 200 fs to 100 ns, and a width of a first part of the scribed groove is 20-80 μm;
in the second laser scribing step, the linearly polarized Gaussian beam emitted by the laser has a wavelength of 355-1064 nm, and a pulse width ranging from 200 fs to 100 ns, and a width of a second part of the scribed groove is 30-200 μm; and
in the third laser scribing step, the linearly polarized Gaussian beam emitted by the laser has a wavelength of 266-532 nm, and a pulse width ranging from 200 fs to 100 ns, and a width of a third part of the scribed groove is 30-100 μm.

8. The laser scribing method of claim 7, wherein in the first laser scribing step, the linearly polarized Gaussian beam emitted by the laser has a wavelength of 1064 nm and a pulse width of 10 ps, and the width of the first part of the scribed groove is 30 μm;
in the second laser scribing step, the linearly polarized Gaussian beam emitted by the laser has a wavelength of 532 nm and a pulse width of 10 ps, and the width of the second part of the scribed groove is 50 μm; and
in the third laser scribing step, the linearly polarized Gaussian beam emitted by the laser has a wavelength of 355 nm and a pulse width of 10 ps, and the width of the third part of the scribed groove is 30 μm.

9. The laser scribing method of claim 8, wherein a power of the laser is 20-90 W, a frequency of the laser is adjustable within a range from 100 kHz to 6 MHz, and a processing speed of the laser is 500-30,000 mm/s.
